(19) United States
(12) Patent Application Publication
(10) Pub. No.: US 2026/0362635 A1
(43) Pub. Date: Nov. 12, 2026

(54) MICRO-CHANNEL COLD PLATE FOR POWER MODULE COOLING

(71) Applicant: FORD GLOBAL TECHNOLOGIES, LLC, Dearborn, MI (US)

(72) Inventors: Man Prakash GUPTA, Dearborn, MI (US); Kewei XIAO, Canton, MI (US); Michael W. DEGNER, Novi, MI (US)

(21) Appl. No.: 19/203,950

(22) Filed: May 9, 2025

(51) Int. Cl. H05K 7/20

(52) U.S. Cl. CPC H05K 7/20254; H05K 7/20272; H05K 7/2039; H05K 7/20927

(57) ABSTRACT

A power module assembly includes a cold plate heat exchanger having a bottom plate defining inlet channels and outlet channels that are isolated from each other, a top plate having a lower side defining a first set of microchannels and a second set of microchannels, and a middle plate disposed between the top plate and the bottom plate and defining distribution channels through a thickness of the middle plate. Each of the distribution channels is in fluid communication with at least one of the inlet channels, one of the outlet channels, a microchannel of the first set, and a microchannel of the second set. The assembly further including a power module disposed on an upper side of the top plate.

### TECHNICAL FIELD

The present invention relates to heat exchangers for power modules used in vehicles.

### BACKGROUND

Vehicles such as battery-electric vehicles (BEVs), plug-in hybrid electric vehicles (PHEVs), and fully hybrid-electric vehicles (FHEVs) contain a traction battery assembly to act as an energy source for one or more electric machines. The traction battery includes components and systems to assist in managing vehicle performance and operations. A power inverter is electrically connected between the battery and the electric machines to convert direct current coming from the battery into alternating current compatible with the electric machines. The power inverter may also act as a rectifier to convert alternating current from the electric machines to direct current compatible with the battery.

### SUMMARY

According to one embodiment, a power module assembly includes a cold plate heat exchanger having a bottom plate defining inlet channels and outlet channels that are isolated from each other, a top plate having a lower side defining a first set of microchannels and a second set of microchannels, and a middle plate disposed between the top plate and the bottom plate and defining distribution channels through a thickness of the middle plate. Each of the distribution channels is in fluid communication with at least one of the inlet channels, one of the outlet channels, a microchannel of the first set, and a microchannel of the second set. The assembly further including a power module disposed on an upper side of the top plate.

According to another embodiment, a power module assembly includes a power module and a cold plate heat exchanger. The heat exchanger includes a bottom plate defining an inlet manifold and an outlet manifold that are isolated from each other, a top plate supporting the power module, and a middle plate sandwiched between the top and bottom plates. The top and middle plates defines a network of cooling channels connecting the inlet manifold in fluid communication with the outlet manifold, and the network includes a first arrangement of channels each in fluid communication with the inlet manifold or the outlet manifold and a second arrangement of channels crisscrossing the first channels such that each channel of the second arrangement is in fluid communication with multiple channels of the first arrangement.

According to yet another embodiment, a heat exchanger includes a bottom plate defining an inlet manifold and an outlet manifold that are isolated from each other; a top plate defining a first set of channels and a second set of channels; and a middle plate disposed between the top plate and the bottom plate and defining a third set of channels through a thickness of the middle plate. The third set of channels are in fluid communication with the inlet manifold, the outlet manifold, the first set of channels, and the second set of channels to define a fluid path within the heat exchanger.

### BRIEF DESCRIPTION OF THE DRAWINGS

FIG. 1 is a diagrammatical view of a vehicle having a power module assembly according to one or more embodiments of this disclosure.

FIG. 2 is a perspective view of a power module assembly.

FIG. 3 is an exploded perspective view of the power module assembly of FIG. 2.

FIG. 4 is a perspective view of a top plate of the power module assembly of FIG. 2.

FIG. 5 is a top view of a bottom plate of the power module assembly of FIG. 2.

FIG. 6 is a top view of a middle plate of the power module assembly of FIG. 2.

FIG. 7 is a negative perspective view of the fluid path of the power module assembly of FIG. 2.

FIG. 8 is a top view of a bottom plate according to an alternative embodiment of this disclosure.

FIG. 9 is a top view of a middle plate according to an alternative embodiment of this disclosure.

FIG. 10 is a bottom view of the middle plate shown in FIG. 9.

FIG. 11 is a top view of a bottom plate according to another alternative embodiment of this disclosure.

FIG. 12 is a bottom view of a top plate according to another alternative embodiment of this disclosure.

FIG. 13 is top view of a middle plate according to another alternative embodiment of this disclosure.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the present invention. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

Used herein, “direct fluid communication” means the fluid flows immediately from one component to the next. Used herein, “indirect fluid communication” refers to components that are connected in fluid communication through one or more intermediaries. The term “fluid communication” covers both. Used herein, a “microchannel” is a channel with a hydraulic diameter below 1 millimeter (mm). Used herein, “substantially” means within plus or minus 3 percent of a stated value.

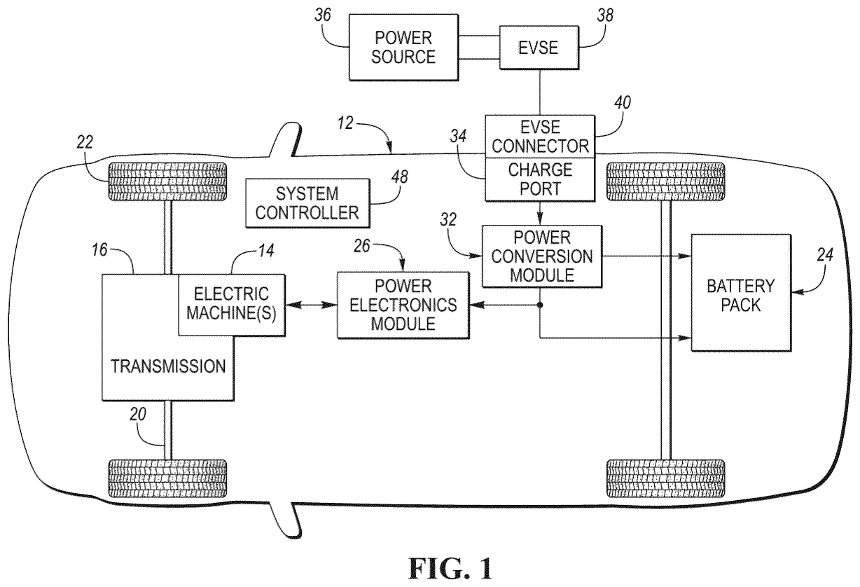

Referring now to FIG. 1, an electrified vehicle (EV) 12 in the form of a battery electric vehicle (BEV) is shown. EV 12 includes a powertrain having one or more traction motors (“electric machine(s)”) 14, a traction battery (“battery” or “battery pack”) 24, and a power electronics module 26 (e.g., an inverter). In the BEV configuration, the traction battery 24 provides all of the propulsion power and EV 12 does not have an engine. In other embodiments, the vehicle may be a hybrid electric vehicle (HEV) further having an engine for providing propulsion power.

The traction motor 14 is part of the powertrain of EV 12 for powering movement of the vehicle. The traction motor 14 may be mechanically connected to a transmission 16 of EV 12, e.g., a one-speed gearbox. The transmission 16 may be mechanically connected to an axle 20 that is mechanically connected to wheels 22 of EV 12. The traction motor 14 can provide propulsion capability to EV 12 and is capable of operating as a generator. The traction motor 14 acting as a generator can recover energy that may normally be lost as heat in a friction braking system of EV 12.

The traction battery 24 stores electrical energy that can be used by the traction motor 14 for propelling EV 12. The traction battery 24 typically provides a high-voltage (HV) direct current (DC) output. The traction battery 24 may be a lithium-ion battery. The traction battery 24 is electrically connected to a power electronics module 26. The traction motor 14 is also electrically connected to the power electronics module 26. The power electronics module 26, such as an inverter, provides the ability to bi-directionally transfer energy between the traction battery 24 and the traction motor 14. For example, the traction battery 24 may provide a DC voltage while the traction motor 14 may require a three-phase alternating current (AC) current to function. The inverter 26 may convert the DC voltage to a three-phase AC current to operate traction motor 14. In a regenerative mode, the inverter 26 may convert three-phase AC current from traction motor 14 acting as a generator to DC voltage compatible with traction battery 24.

The traction battery 24 may be rechargeable by an external power source 36 (e.g., the grid). The external power source 36 may be electrically connected to electric vehicle supply equipment (EVSE) 38. EVSE 38 provides circuitry and controls to control and manage the transfer of electrical energy between external power source 36 and EV 12. An external power source 36 may provide DC or AC electric power to the EVSE 38. The EVSE 38 may have a charge connector 40 for plugging into a charge port 34 of (EV) 12.

A power conversion module 32 of EV 12, such as an on-board charger having a DC/DC converter, may condition power supplied from EVSE 38 to provide the proper voltage and current levels to the traction battery 24. A power conversion module 32 may interface with EVSE 38 to coordinate the delivery of power to the traction battery 24.

The various components described above may have one or more associated controllers to control and monitor the operation of the components. The controllers can be microprocessor-based devices. The controllers may communicate via a serial bus (e.g., Controller Area Network (CAN)) or via discrete conductors.

For example, a system controller 48 (“vehicle controller”) is present to coordinate the operation of the various components. The controller 48 includes electronics, software, or both, to perform the necessary control functions for operating EV 12. In embodiments, controller 48 is a combination vehicle system controller and powertrain control module (VSC/PCM). Although the controller 48 is shown as a single device, controller 48 may include multiple controllers in the form of multiple hardware devices, or multiple software controllers with one or more hardware devices. In this regard, a reference to a “controller” herein may refer to one or more controllers.

The power electronics module 26 and power conversion module 32 are power modules that handle high-voltage (HV) electrical power in their operations. For instance, the inverter of power electronics module 26 converts HV DC electrical power from the traction battery 24 into the requisite AC electrical power for driving the traction motor 14. The DC/DC converter of the power conversion module 32 converts AC electrical power from the grid 36 into HV DC electrical power for charging the traction battery 24. The power electronics module 26 may further include its own DC/DC converter for use in converting the HV DC electrical power from the traction battery 24 into a lower voltage DC electrical power for the inverter to invert into the requisite AC electrical power for driving the traction motor 14.

The power electronics module 26 and power conversion module 32 include corresponding electronics assemblies for performing their associated electrical power operations. Each electronics assembly may include one or more power stages having a transistor-based switching arrangement, such as one or more half-bridges. Each half bridge may include first and second electrical switching units with each switching unit including a transistor connected in anti-parallel with a diode. Each half bridge may include a positive DC lead and a negative DC lead between which the first and second switching units are connected. The half bridges of the inverter of power electronics module 26 may further include one or more AC output leads (e.g., three AC output leads for three-phase power) electrically connected to the traction motor 14.

Power modules such as power electronics module 26 and power conversion module 32 generate heat during operation. Proper cooling is desired for the reliable operation of the power modules. The cooling technique used for a power module directly affects the size of the power module as a better cooling approach can allow higher power density in the power module. In addition to size reduction, other considerations such as reliability, manufacturing expense, lower parasitic, ease of assembly, etc., are relevant design criteria for power modules.

The present disclosure provides a power module cooling arrangement that addresses many of the relevant design criteria. The power module cooling arrangement may be for a power inverter such as power electronics module(s) 26 or for a power converter such as power conversion module 32, as described above, or may be for another type of electronics. In general, the cooling arrangement includes a heat exchanger having an internal cooling network having a plurality of cooling channels, some of which may be some microchannels. The design of the power module assembly and heat exchanger will now be described in greater detail.

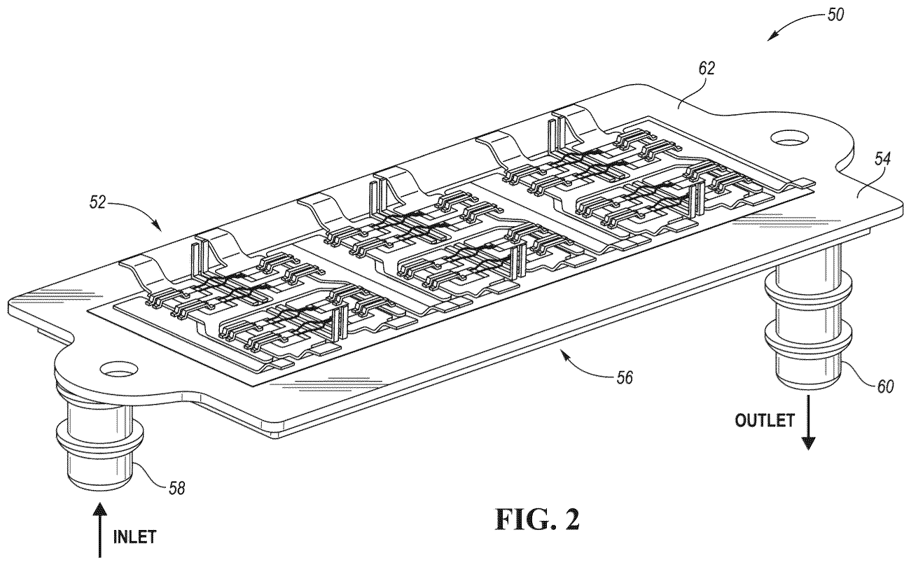

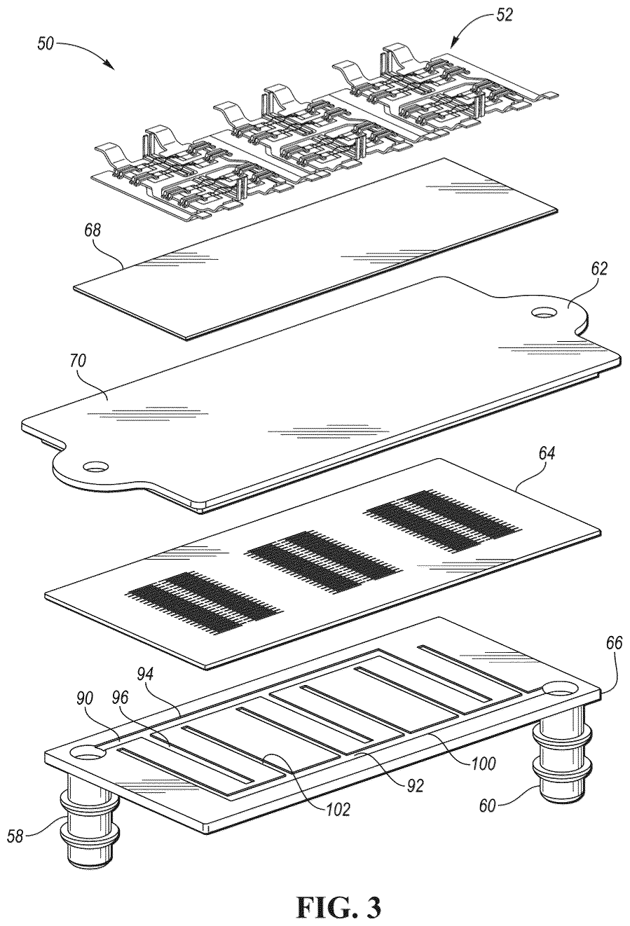

Referring to FIGS. 2 and 3, power module assembly 50 includes a plurality of power modules 52 that are heated, cooled, or both by a cold plate heat exchanger 54. The power modules may be arranged in a linear row on top of the cold plate 54. That is, the power modules 52 are shown in a planar arrangement. In the illustrated embodiment, three power modules 52 are shown, but more or fewer may be used in other embodiments.

The heat exchanger 54 is part of a liquid-cooling system that circulates a working fluid commonly referred to as coolant. The working fluid may be a water-based such as a mixture of water and ethylene glycol. This is just an example, however, and any suitable working fluid may be used with the heat exchanger 54. The heat exchanger 54 includes a body 56 that defines an internal network having cooling channels or passages. The working fluid is provided to and from the cooling network by an inlet port 58 and an outlet port 60. The inlet and outlet ports 58, 60 are shown as projecting from the bottom of the body 56 but this is just one example embodiment. In other embodiments, one or more of the ports may extend from the side of the body 56. For example, the ports may be provided on opposing sides of the body. Alternatively, both ports may extend from a same side of the body. It is also possible for the ports to extend from the top of the body 56 provided there is sufficient clearance for the power modules 52.

The body 56 of the heat exchanger 54 may be formed of a top plate 62, a middle plate 64, and a bottom plate 66. The plates include features and cooperate such that the features define the cooling network within the body 56. For example, each of the plates may define channels or grooves that form a segment of the internal cooling network. The channels may be cut, or formed, otherwise recessed into the plates. Some of the cooling channels may extend completely through a thickness of the plate while others only extend partially through the thickness of the plate. The plates may be formed of any suitable material depending upon the location of the plate and its intended purpose. The upper side 70 of the top plate 62 engages, directly or indirectly through a thermally conductive material 68, with the power modules 52 and is formed of a material with high thermal conductivity to facilitate efficient heat transfer between the power modules 52 and the working fluid. For example, the top plate 62 may be formed from metal such as aluminum or copper. The middle plate 64 and the bottom plate 66 do not engage with the power modules 52 and may be formed from a material that does not have high thermal conductivity. For example, the middle plate 64 and the bottom plate 66 may be formed from a lightweight material such as plastic. Alternatively, the middle plate 64 and the bottom plate 66 may be formed from metal. Forming all of the plates from metal increases the thermal mass of the body 58 and may increase the cooling capacity of the heat exchanger 54. The joints of the plates 62, 64, and 66 are sealed to prevent leakage from the body 56. The joints may be sealed by any suitable method or combination of methods such as gaskets, O-rings, adhesive, welding, brazing, soldering, or the like.

According to one or more embodiments, the cooling network may start at the bottom plate 66, circulate to the middle plate 64 that distributes the coolant to the top plate 62. The cooling network then circulates across the top plate 62, across and through the middle plate 64, and finally back to the bottom plate 66 for exit through the outlet port 60.

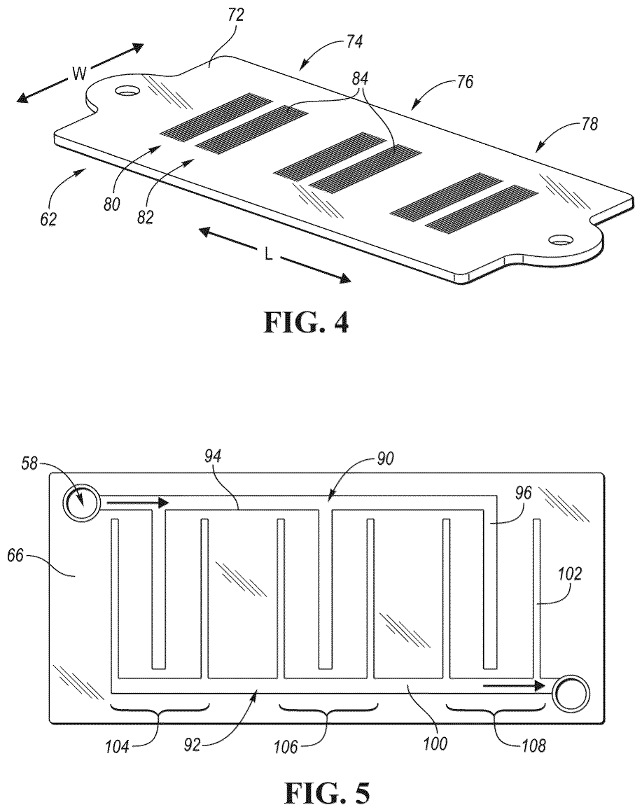

Referring to FIG. 4, the top plate 62 defines channels, e.g., microchannels, that are recessed into the bottom side 72 of the top plate 62. In the example embodiment, the channels are arranged in three sets 74, 76, and 78. Each of the sets includes a first bank of channels 80 and a second bank of channels 82. Each bank includes a plurality of individual channels 84. The channels may be straight and parallel to each other with small spacing therebetween. As shown in the illustrated example, the spacing between the channels approximates the width of the channels. In the microchannel example shown, this results in a high density of parallel channels. The parallel channels 84 may extend in the width direction (W) of the top plate 62. Within each set, the banks 80, 82 are spaced apart from each other in the length direction (L) of the top plate 62. The spacing between the banks is much greater than the spacing between adjacent channels 84.

Referring to FIGS. 2 and 4, the placement of the channels sets 74, 76, 78 corresponds with the location of the power modules 52 on the heat exchanger 54. That is, each of the power modules 52 includes an associated set of cooling channels recessed into the top plate 66. Additionally, the location of the banks 80 and 82 corresponds with the location of the microchips on each individual power module 52. The microchips generate lots of heat; therefore, the banks 80 and 82 may be disposed directly under the microchips to provide coolant flow targeted at the hottest area of the power modules 52. While the above-described embodiment of the heat exchanger 54 is designed specifically to maximize cooling of the shown power modules 52, in other embodiments, the heat exchanger 54 is designed for universal use with many different power modules.

Referring to FIGS. 3 and 5, the bottom plate 66 defines recessed grooves that form the inlet and outlet manifolds 90, 92. The inlet manifold 90 is in fluid communication with the inlet port 58 and includes a plurality of channels or segments interconnected to form a fluid supply circuit. For example, the inlet manifold 90 includes a main channel 94 and a plurality of branching channels 96. Similarly, the outlet manifold 92 is in fluid communication with the outlet port 60 includes a plurality of channels or segments interconnected to form a fluid return circuit. For example, the outlet manifold 90 includes a main channel 100 and a plurality of branching channels 102.

In the illustrated example, the main channels 94 and 100 extending in the longitudinal direction of the bottom plate 66 and the branching channels 96 and 102 extend in the width direction of the bottom plate 66. The main channels 94, 100 are disposed on opposite sides of the bottom plate 66 with the branching channels 96, 102 extending towards the opposing main channel. This causes the branching channels 96, 102 to be interleaved with each other. As best seen in FIG. 5, the inlet manifold 90 is completely separate from the outlet manifold 92. As described in more detail below, channeling disposed in the other plates of the heat exchanger fluidly connect the inlet an outlet manifolds 90, 92 with each other.

The branching channels 96, 102 are arranged in sets 104, 106, and 108. Each set corresponds with one of the power modules 52. That is, set 104 is associated with the set 74 of the top plate 62, set 102 is associated with the set 76, and set 108 is associated with the set 78. In this example, each set includes a single, central inlet branch 96 sandwiched between two outlet branches 102. The cross-sectional area of the inlet branches 96 may be greater than any one of the outlet branches 102 due to the fact that there are twice as many outlet branches as inlet branches. In some embodiments, the cross-sectional area of the inlet branch 96 is twice as much as the cross-sectional area of the outlet branch 102. In other embodiments, this arrangement may be flipped with more inlet branches than outlet branches.

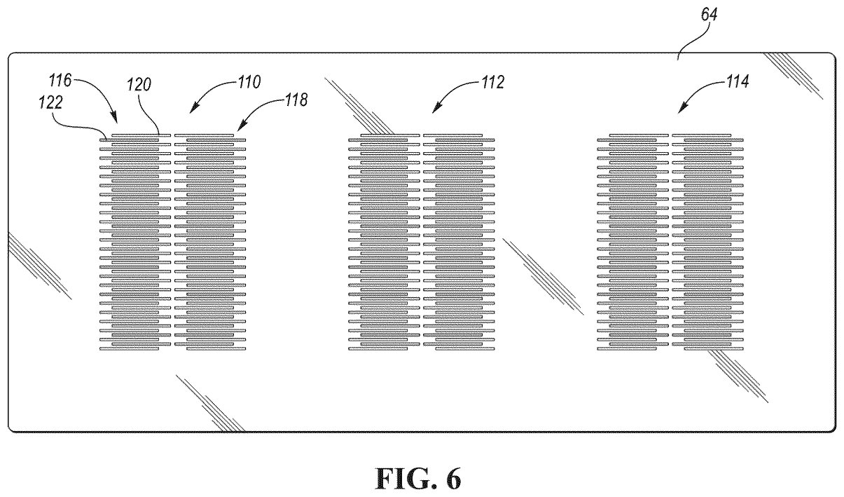

Referring to FIG. 6, the middle plate 64 defines distribution channeling that connects the manifolds 90, 92 of the bottom plate 66 in fluid communication with the channeling of the top plate 62. The distribution channeling may be microchannels. The middle plate 64 may define dedicated channels for supplying fluid from the inlet manifold 90 to the channeling of the top plate 62 and dedicated channels for returning fluid from the channeling of the top plate 62 to the outlet manifold 92.

Like described above, the channeling of the middle plate 64 is arranged in sets, such as sets 110, 112, and 114. The set 110 is associated with the set 74 and set 104; the set 112 is associated with the set 76 and set 106; and the set 114 is associated with the set 78 and set 108. Each set 110, 112, 114 may include a pair of rows of channels 116 and 118. In the illustrated example, the rows 116, 118 are placed side-by-side and extend in the width direction of the bottom plate 64. Each row includes supply channels 120 and return channels 122 that extend in the length direction of plate 64.

In the illustrated embodiment, the supply and return channels 120, 122 alternate one after the other along the longitudinal direction of the row. The supply channels 120 are in fluid communication with the inlet branches 96 but not the outlet branches 102. The return channels 122 are in fluid communication with the outlet branches 102 but not the inlet branches 96. Thus, the supply channels 120 convey fluid from the inlet branches 96 to the channels 84 of the top plate and the return channels 122 convey fluid from the channels 84 of the top plate to the outlet branches 102. The supply and return channels 120, 122 may be parallel to each other and have the same length. They may also have the same cross-sectional area and be equally spaced from each other. This is just one example, and other configurations are contemplated. Within each set, the supply channels 120 are shifted towards the center of the set to be in fluid communication with the central inlet branch 96 but not the outer outlet branches 102. The return channels are shifted outwards to be in fluid communication with the outlet branches 102 but not the inlet branch 96. In other embodiments, the location of the supply and return channels 120, 122 may be flipped to match a flipped bottom plate as described above.

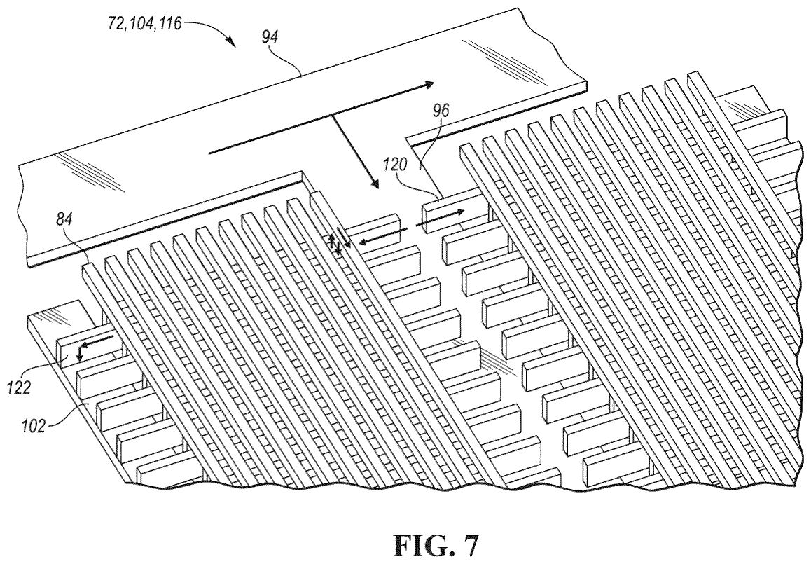

FIG. 7 illustrates the cooling network within the heat exchanger 54. In FIG. 7, the void space of the cooling network is shown as a solid and all solid material is removed. That is, FIG. 7 is a negative. FIG. 7 illustrates a portion of the cooling channels of the sets 72, 104, and 116. The fluid flow through the heat exchanger 54 will now be described. Coolant enters through the inlet Port 58 and is supplied to the main line 94 of the inlet manifold 90. From there, coolant flows to the inlet branches 96. The inlet branches 96 are in fluid communication with the supply channels 120 that are located above. The pump of the liquid-cooling system forces the fluid up from the inlet branches 96 into the supply channels 120. The channels 84 of the top plate crisscross with the supply channels 120 and the return channels 122. For example, the channels 84 are orthogonal to the supply and return channels 120, 122 as shown. The fluid then traverses through the channels 84 absorbing heat from the power modules 52. The fluid traveling through the channels 84 is presented with a plurality of different exits as the channels 84 crisscross with the return channels 122. The return channels 122 are directly below the channels 84 so that fluid may flow downwardly to exit the channels 84. The fluid then travels along the return channels 122 and exits into the outlet branches 102 for circulation to the outlet port 60. This crisscrossing network of channels provides a highly distributed network of exit points for the fluid, which reduces pressure dropped despite the limited size of the microchannels. It also ensures that a relatively cold coolant is in contact with the top plate 62 as most individual molecules of coolant are unlikely to remain in the channels 84 for an extended period of time.

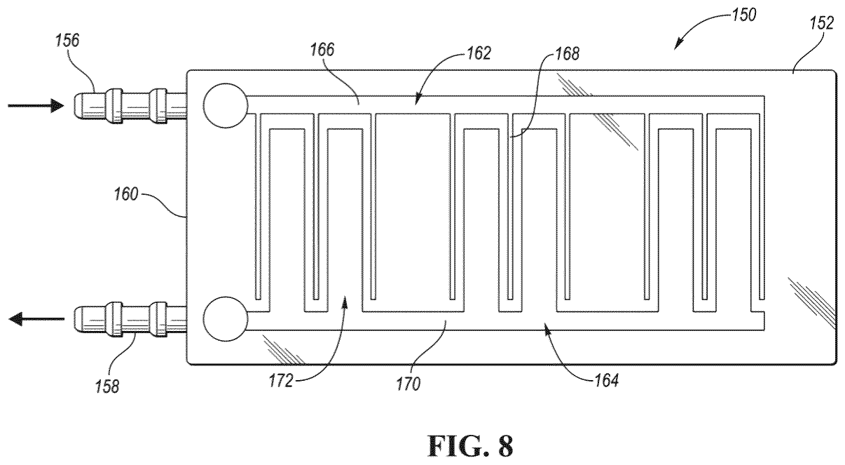

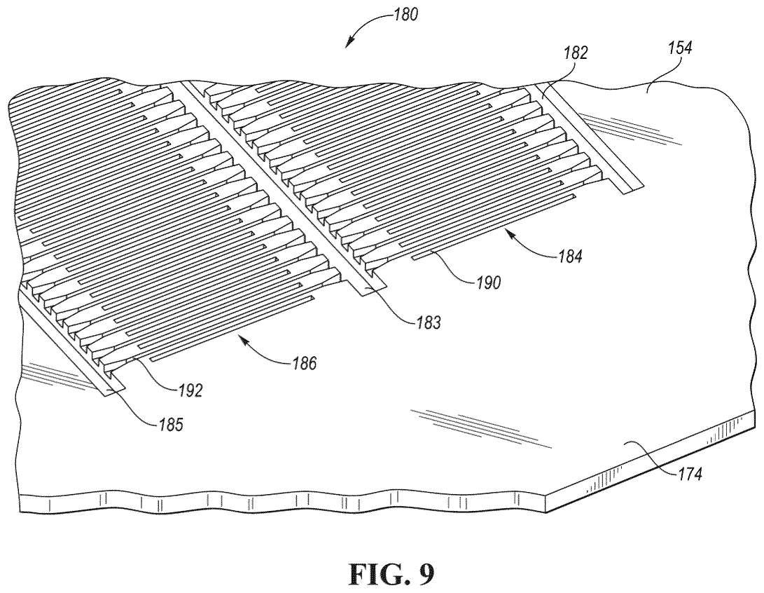

FIG. 8-10 discloses an alternative arrangement of the internal cooling network within a heat exchanger 150. Like above, the heat exchanger 150 includes a bottom plate 152, a middle plate 154 and a top plate (not shown) that may be the same as the above-described top plate. The bodies of the bottom and middle plate 152, 154 may be as described above but the channeling is different creating an alternative arrangement of the internal cooling network.

Referring to FIG. 8, in this example, the inlet port 156 and the outlet port 158 are located on the side 160 of the bottom plate 152. Like above, channels or grooves are recessed into the top surface 162 of the bottom plate 152. Also like above, the bottom plate 152 defines recessed grooves that form the inlet and outlet manifolds 162, 164. The inlet manifold 162 is in fluid communication with the inlet port 156 and includes a plurality of channels or segments that are interconnected to form a fluid supply circuit. For example, the inlet manifold 162 includes a main channel 166 and a plurality of branching channels 168. Similarly, the outlet manifold 164 is in fluid communication with the outlet port 158 and includes a plurality of channels or segments interconnected to form a fluid return circuit. For example, the outlet manifold 164 includes a main channel 170 and a plurality of branching channels 172. The branching channels 168 and 172 are again arranged in sets as described above.

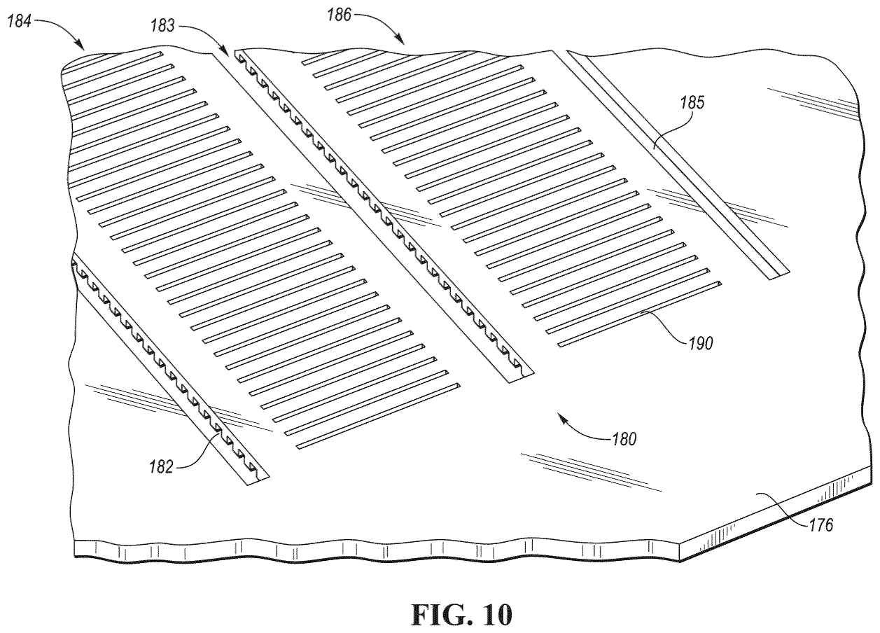

Referring to FIGS. 9 and 10, the middle plate 154 includes a top side or surface 174 and a bottom side or surface 176. The middle plate 154 defines channels arranged in sets and rows as described above albeit with different channel configurations. In this embodiment, each set 180 includes three fluid supply channels 182, 183, 185 and extended in the width direction of the middle plate 154. A row of first channels 184 is located between the left fluid supply channel 182 and the middle fluid supply channel 183, and a row of second channels 186 is located between the center channel 183 and the outer channel 185. Each row of channels 184, 186 includes through channels 190 (slots) that extend through the thickness of the middle plate 154 as well as partially recessed channels 192 that do not extend through the thickness of the plate 154. The channels 190 and 192 are arranged orthogonal to the longitudinal direction of the rows 184, 186 and alternate one after the other in this example. Other alternating arrangements are contemplated. The through channels 190 are isolated from the supply channels 182, 183, 185, whereas the recessed channels 192 are in fluid communication with both of their associated fluid supply channels. For example, the channels 192 of row 184 extend from supply channel 182 to supply channel 183. As previously discussed, the channels of the top plate crisscross, e.g., at a perpendicular angle, the channels 190, 192 and receive fluid therefrom.

When the plates of the heat exchanger are stacked together after final assembly, the fluid channels 182, 183, 185 are above and in fluid communication with the supply branches 168 and the channels 190 and 192 are above and in fluid communication with the outlet branches 172. The channels of the top plate are above the channels 190 and 192 and are in fluid communication therewith. The channels of the top plate are arranged to not be in direct fluid communication with the fluid inlet channels 182, 183, 185.

During operation, the inlet manifold 162 supplies fluid to the supply channels 182, 183, 185 of the middle plate 154 via the supply branches 168. The fluid then flows upwardly through the thickness of the middle plate 154 and into the recessed channels 192. From there, the fluid flows upwardly into the channels of the top plate. The fluid then flows along the channels of the top plate to be placed in fluid communication with the through channels 190 of the middle plate 154. The through channels 190 conveyed the fluid down through the thickness of the plate 154 and into the return branches 172 of the outlet manifold 164. The heated fluid then exits the heat exchanger via the outlet port 158.

The above-described heat exchangers provide efficient cooling through the use of microchannels while maintaining pressure dropped to acceptable levels. The above-described heat exchangers each has a three-dimensional flow path that provides increased surface area and highly turbulent flow to more efficiently cool the assembly 150. These enhancements cooperate to reduce the temperature differential of the system and boost overall cooling performance among other things.

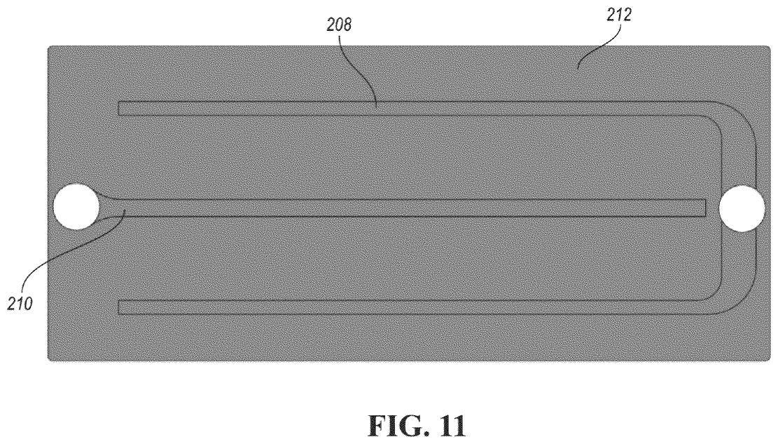

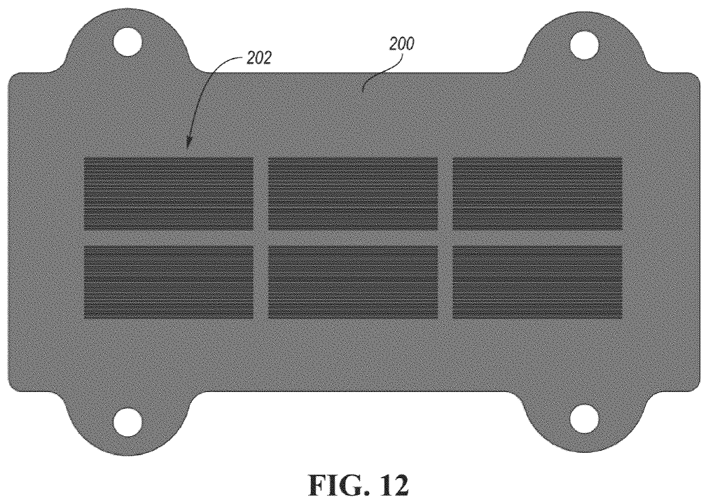

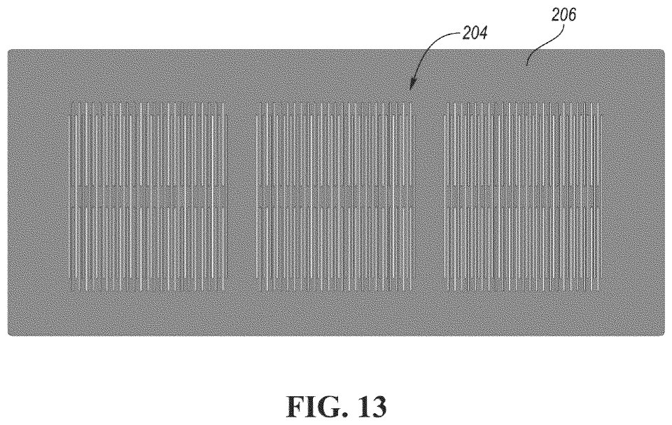

The above-described orientations of the channels may be different in other embodiments. For example, FIGS. 11, 12, and 13 show a power module that is similar to the first embodiment but with the channels 202 of the top plate 200 being oriented to extend in the longitudinal (length) direction of the top plate. The channels 204 are oriented to extend in the latitudinal (width) direction of the middle plate 206 to crisscross with the channels 202 as described above. The inlet and outlet channels 208, 210 of the bottom plate 212 are modified relative to the first embodiment to match the change in orientation of the channels 204.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to strength, durability, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and can be desirable for particular applications.

What is claimed is:

1. A power module assembly comprising:
a cold plate heat exchanger including:
a bottom plate defining inlet channels and outlet channels that are isolated from each other;
a top plate having a lower side defining a first set of microchannels and a second set of microchannels, and
a middle plate disposed between the top plate and the bottom plate and defining distribution channels through a thickness of the middle plate, wherein each of the distribution channels is in fluid communication with at least one of the inlet channels, one of the outlet channels, a microchannel of the first set, and a microchannel of the second set; and
a power module disposed on an upper side of the top plate.

2. The power module of claim 1, wherein each of the microchannels of the first and second sets of microchannels extends in a first direction of the cold plate, and the distribution channels extend in a second direction of the cold plate.

3. The power module of claim 2, wherein the first and second directions are substantially orthogonal to each other.

4. The power module of claim 2, wherein the microchannels of the first set are parallel to each other, the microchannels of the second set are parallel to each other, and the microchannels of the first set are parallel to the microchannels of the second set.

5. The power module of claim 1, wherein the first and second sets of microchannels forms a cooling bank, wherein the power module is disposed on the upper side directly above the cooling bank.

6. The power module of claim 5, wherein the top plate defines a plurality of the cooling banks, and the power module is a plurality of power modules equal in number to the banks, wherein each power module is disposed on the upper side directly above a corresponding one of the banks.

7. The power module of claim 1 further comprising a thermal interface material disposed between the top plate and the power module.

8. A power module assembly comprising:
a power module; and
a cold plate heat exchanger including a bottom plate defining an inlet manifold and an outlet manifold that are isolated from each other, a top plate supporting the power module, and a middle plate sandwiched between the top and bottom plates, wherein the top and middle plates define a network of cooling channels connecting the inlet manifold in fluid communication with the outlet manifold, and the network includes a first arrangement of channels each in fluid communication with the inlet manifold or the outlet manifold and a second arrangement of channels crisscrossing the first channels such that each channel of the second arrangement is in fluid communication with multiple channels of the first arrangement.

9. The power module assembly of claim 8, wherein the first arrangement of channels are parallel to each other, and the second arrangement of channels are parallel to each other.

10. The power module assembly of claim 9, wherein the first arrangement of channels are orthogonal to the second arrangement of channels.

11. The power module assembly of claim 8, wherein the first arrangement of channels are defined by the middle plate.

12. The power module assembly of claim 11, wherein the second arrangement of channels are defined by the top plate.

13. The power module assembly of claim 8, wherein the power module is disposed on the top plate directly above the second arrangement of channels.

14. The power module assembly of claim 8, wherein the power module is a plurality of power modules disposed on the top plate, and wherein the network of cooling channels is a plurality of networks of cooling channels each associated with a corresponding one of the power modules.

15. The power module assembly of claim 8, wherein the second arrangement of channels includes a first set of the channels that are parallel to each other and spaced equidistant by a first distance and a second set of the channels that are parallel to each other and spaced equidistant by a second distance.

16. The power module assembly of claim 15, wherein the first set and the second set are spaced from each other by a third distance that is greater than the first and second distances.

17. A heat exchanger comprising:
a bottom plate defining an inlet manifold and an outlet manifold that are isolated from each other;
a top plate defining a first set of channels and a second set of channels; and
a middle plate disposed between the top plate and the bottom plate and defining a third set of channels through a thickness of the middle plate, wherein the third set of channels are in fluid communication with the inlet manifold, the outlet manifold, the first set of channels, and the second set of channels to define a fluid path within the heat exchanger.

18. The heat exchanger of claim 17, wherein the first set of channels and the second set of channels are parallel to each other.

19. The heat exchanger of claim 17, wherein one of the inlet manifold and the outlet manifold includes a pair of manifold channels, and wherein each of the channels of the third set of channels is in fluid communication with only one of the pair of manifold channels.

20. The heat exchanger of claim 17, wherein the third set of channels are orthogonal to the first and second sets of channels.
